(19) United States
(12) Patent Application Publication
(10) Pub. No.: US 2010/0308904 A1
(43) Pub. Date: Dec. 9, 2010

(54) DEVICE FOR GENERATING A REFERENCE VOLTAGE DESIGNED FOR A SYSTEM OF THE SWITCHED-CAPACITOR TYPE

(75) Inventors: Hugo Gicquel, Grenoble (FR); Marc Sabut, Eybens (FR); Fabien Reaute, Renage (FR)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics (Grenoble 2) SAS, Grenoble (FR)

(21) Appl. No.: 12/792,930

(22) Filed: Jun. 3, 2010

(30) Foreign Application Priority Data
Jun. 3, 2009 (FR) 0953653

(51) Int. Cl. H01L 25/00

(52) U.S. Cl. 327/563; 330/185

(57) ABSTRACT

The device generates a reference voltage, in particular designed for a system of the switched-capacitor type, based on a setpoint voltage. It includes a regulation loop having a first input to receive the setpoint voltage, and an output stage arranged as a voltage follower and looped to a second input of the loop. An additional stage is configured to deliver the reference voltage to the switched-capacitor system, this additional stage, coupled to the output stage, also being arranged as a voltage follower and paired with the output stage.

### FIELD OF THE INVENTION

The invention relates to electronic circuits, and, more particularly, to the generation of a reference voltage, for example designed for a switched-capacitor system.

### BACKGROUND OF THE INVENTION

The accuracy of a switched-capacitor system may be very tightly linked to the accuracy of the reference voltage. For example, in a 12-bit analog-to-digital convertor with a pipeline architecture with a dynamic range of 2 Vpp (twice the peak-peak voltage), the least significant bit (LSB) corresponds to a voltage of 500 microvolts, which means a precision of the reference voltage of the order of 100 microvolts.

In conventional approaches the reference voltage delivered to a switched-capacitor system is usually produced by a regulation loop comprising a follower operational amplifier receiving a setpoint voltage at the input. A major drawback of such an implementation lies, as illustrated in FIG. 1, in the fact that the average value of the reference voltage VREF is regulated to the setpoint value VBG, but this average value is different from the values at the end-of-convergence points.

It should be noted that in a switched-capacitor environment, the value at each end-of-convergence point is to be taken into account since it is this value that is sampled for the next clock cycle. The result of this is therefore, as illustrated in FIG. 1, values at the end-of-convergence points that are dependent on the activity of the switched-capacitor system.

More precisely, although in the case of no activity of the switched-capacitor system, the reference value VREF is naturally equal to the setpoint value VBG, it is not the case in the case of activity. The values of the reference voltage VREF at the end-of-convergence points also differ depending on the volume of activity.

In the case of low activity, that is to say if, for example, the value of the capacitance of the switched-capacitor system is low or else if the switching frequency of the commutators is low, the values at the end-of-convergence points, although different from the setpoint value VBG, remain close to this setpoint value. In contrast, this is not so in the case of high activity (considerable capacitance and/or high switching frequency).

A second drawback lies in the time taken to establish the setpoint voltage, which depends on the bandwidth of the regulation loop. High switching frequencies make the bandwidth requirements difficult to achieve and at the price of high consumption. This is why the node at which the reference voltage VREF is present is usually connected to an external capacitor with a high capacitive value. The latter then acts as a supplier of instantaneous capacitive charge, which makes it possible to relax the requirements concerning the bandwidth of the loop, that is to say the direct-current loop. This approach cannot however be used in a fully integrated system.

### SUMMARY OF THE INVENTION

According to one embodiment, a device is for generating a reference voltage designed for a system of the switched-capacitor type, making it possible to regulate the values at the end-of-convergence points to the setpoint value, and to do so in a manner independent of the activity. Also proposed is a device for generating such a reference voltage that can be fully integrated.

According to one aspect, a device for generating a reference voltage is thus proposed, in particular designed for a system of the switched-capacitor type, the reference voltage being generated based on setpoint voltage. According to a general feature of this aspect, the device comprises a regulation loop, having a first input in order to receive the setpoint voltage, and an output stage arranged as a voltage follower and looped to a second input of the loop. The device comprises an additional stage configured to deliver the reference voltage, this additional stage, coupled to the output stage, also being arranged as a voltage follower and paired with the output stage.

With such a structure, in an application with a switched-capacitor system, the switched-capacitor system is decoupled from the output stage of the regulation loop and each end-of-convergence point is then the quiescent point or equilibrium point of the output stage, that is to say that the value of each end-of-convergence point becomes equal to the equilibrium value of the loop, that is to say the value of the setpoint voltage. Although the structure of the reference voltage generation device can be a structure with a single input (“single ended” as it is called by those skilled in the art), the device advantageously has a differential structure and the additional stage then comprises two output terminals delivering the differential reference voltage.

According to one embodiment, the output stage includes at least one output circuit comprising an output NMOS transistor mounted as a follower with an output resistive module, connected in series between two power supply terminals, and an output element forming an output PMOS transistor mounted as a follower with the output resistive module. The additional stage includes at least one additional circuit comprising, connected in series between two power supply terminals, an additional NMOS transistor mounted as a follower with an additional resistive module and an additional element forming an additional PMOS transistor mounted as a follower with the additional resistive module.

The gates of the NMOS transistors are connected together and the elements forming the PMOS transistor are connected together, the two terminals of the additional resistive module forming the two output terminals capable of delivering the differential reference voltage. The output element forming a PMOS transistor may be a PMOS transistor, and the additional element forming a PMOS transistor may be a PMOS transistor. In this case, the gates of the PMOS transistor are connected together.

In contrast, depending on the technology used, in particular with technologies having low threshold voltages of the MOS transistors and low power supply voltages, it is particularly advantageous to be able to emulate the output element forming a PMOS transistor by using an NMOS transistor mounted as a “high frequency” diode (because the drain-source connection is provided by a capacitor), which makes it possible to prevent the gate voltage from descending to negative values (below earth).

More precisely, according to such an embodiment, the output element forming a PMOS transistor and the additional element forming a PMOS transistor comprise a first NMOS transistor mounted as an NOT gate coupled to a first capacitor, a second NMOS transistor mounted as an NOT gate coupled to a second capacitor, and a switched-capacitor module mounted in parallel with the first capacitor and the second capacitor, the gates of the NMOS transistors mounted as NOT gates being connected together via the switched-capacitor module. The second NMOS transistor coupled to the second capacitor serves as a high-frequency diode.

The coefficient of pairing between the output stage and the additional stage is of lesser importance. According to one embodiment, each output circuit is identical to each additional circuit, and the degree of pairing is achieved by the ratio between the number of additional circuits and the number of output circuits. When it is desired to deliver a relatively high current to the switched-capacitor system, it is preferable that the additional stage comprises a number of identical additional circuits connected in parallel, this number being greater than the number of output circuits of the output stage. The user will therefore choose, for example, a structure comprising one output circuit and several identical additional circuits connected in parallel.

According to one embodiment, the device also comprises a band gap voltage generator comprising a terminal stage having a resistor, advantageously having a programmable or adjustable value, connected in series between two transistors mounted as a current source. The regulation loop comprises a differential operational amplifier having a first input forming the first input of the regulation loop and connected to one of the terminals of the resistor of the terminal stage in order to receive a floating band gap voltage as a setpoint voltage. The operational amplifier comprises a second input forming the said second input of the regulation loop. The output resistive module of the output circuit of the output stage comprises two output resistors.

The regulation loop comprises a comparator having a first input connected to the common terminal of the two output resistors, a second input to receive a common-mode voltage, and an output connected to a common-mode input of the differential amplifier. The other terminal of one of the two resistors is connected to the second input of the differential amplifier, while the other terminal of the other resistor is connected to the other terminal of the resistor of the said terminal stage of the band gap voltage generator.

When the power supply voltage is lower than the reference voltage to be delivered, the differential operational amplifier may advantageously be associated with a charge pump the output of which is connected to the gate of the output NMOS transistor of each output circuit. According to another aspect, an electronic assembly is proposed comprising a device of the type defined above for generating a reference voltage, connected to a system of the switched-capacitor type.

### BRIEF DESCRIPTION OF THE DRAWINGS

Other advantages and features of the invention will appear on examination of the detailed description of embodiments that are in no way limiting and of the appended drawings in which:

FIG. 1, already described, illustrates the drawbacks of a prior art device;

FIG. 2 illustrates schematically an embodiment of a device according to the invention;

FIG. 3 illustrates in greater detail an embodiment of a portion of the device of FIG. 2;

FIG. 4 illustrates in greater detail another exemplary differential embodiment of a device according to the invention;

FIG. 5 illustrates an example of the invention using a charge pump; and

FIG. 6 illustrates a differential embodiment in greater detail of a device according to the invention.

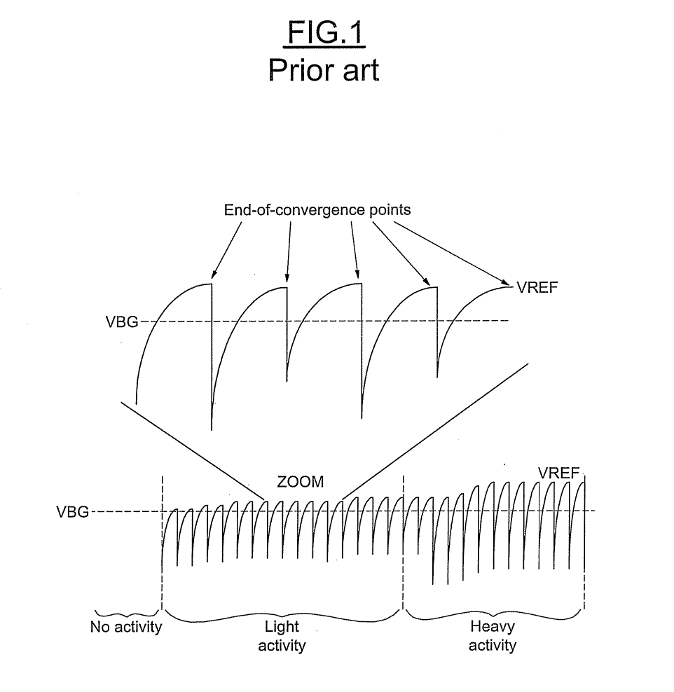

### DETAILED DESCRIPTION OF THE PREFERRED EMBODIMENTS

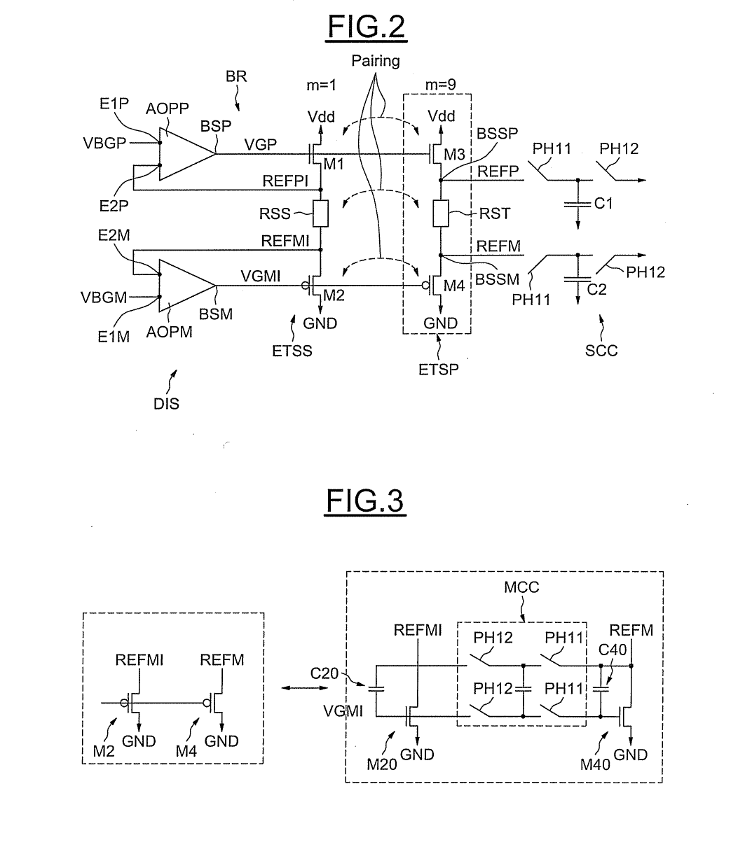

In FIG. 2, the reference DIS indicates in a general manner a device for generating a reference voltage, in this instance a differential reference voltage REFP, REFM. The device DIS is, in this particular application, connected to a switched-capacitor system SCC comprising two capacitors C1 and C2 capable of being successively charged and discharged via the differential reference voltage via switches controlled by control signals PHI1 PHI2. The device DIS comprises a regulation loop BR, in this instance of differential structure.

The regulation loop comprises in this instance two operational amplifiers AOPM and AOPP. The operational amplifier AOPP comprises a first input E1P while the amplifier AOPM comprises a first input E1M. These first two inputs E1P and E1M form a differential input in order to receive a differential setpoint voltage VBGP, VBGM. The amplifier AOPP comprises a second input E2P and the amplifier AOPM comprises a second input E2M.

Also provided is an output stage ETSS arranged as a voltage follower and looped to the second inputs E2P and E2M of the amplifiers AOPP and AOPM. The output stage ETSS comprises an output circuit connected between two power supply terminals, namely the power supply voltage Vdd and the earth GND.

This circuit comprises, connected in series between the two power supply terminals, an NMOS transistor M1 mounted as a follower with a resistive module formed in this instance of a resistor RSS, and a PMOS transistor M2 mounted as a follower with the resistor RSS. More precisely, the drain of the transistor M1 is connected to the voltage Vdd while the gate of the transistor M1 is connected to the output terminal BSP of the amplifier AOPP and receives the voltage VGP.

The source of the transistor M1 at which the voltage REFPI is present is connected to the resistor RSS. The drain of the transistor M2 is connected to earth. Its gate, which receives the voltage VGMI, is connected to the output terminal BSM of the amplifier AOPM and the source of the transistor M2, at which the voltage REFMI is present, is connected to the other terminal of the resistor RSS.

The device DIS also comprises an additional stage ETSP. This additional stage ETSP comprises at least one additional circuit, with a structure identical to that of the output circuit of the output stage. Each additional circuit therefore comprises, connected in series between the power supply voltage Vdd and earth GND, an NMOS transistor M3 mounted as a follower with an additional resistive module formed in this instance of a resistor RST, and a PMOS transistor M4 mounted as a follower with the resistor RST.

The gates of the transistors M1 and M3 are connected together and the gates of the transistors M2 and M4 are connected together. Moreover, the sources of the transistors M3 and M4 are respectively connected to the two terminals of the resistor RST and form two output terminals BSSP and BSSM capable of delivering a differential reference voltage REFP, REFM to the switched-capacitor system SCC.

The additional stage ETSP is paired (at the output stage ETSS). The coefficient of pairing is in this instance equal to 9. In practice, with respect to the transistors, this can be achieved with a transistor M3 having a channel width nine times greater than the width of the channel of the transistor M1. The same may apply for the PMOS transistor. This being so, in practice, this pairing may take the form of the parallel connection of nine additional circuits of identical structure to that of the output circuit M1, RSS and M2.

Having a pairing ratio of 1 to 9 between the output stage and the additional stage makes it possible, in this instance, to deliver a relatively high charge current to the SCC system. Each end-of-convergence point is reached when the capacitor C1 (respectively C2) is charged to the voltage REFP (respectively REFM).

At this moment, there is no longer current passing into the capacitors C1 and C2, and the current that passes into the resistor RST is equal to the quiescent current of the output stage ETSS, that is to say to the current that passes into the resistor RSS. At this moment, because of the structure used and because of the pairing between the stages, the voltage REFP, REFM is equal to the equilibrium voltage REFPI, REFMI, that is to say to the desired setpoint voltage.

This therefore gives at the output of the device, that is to say at the terminals BSSP and BSSM, a reference voltage the value of which at each end-of-convergence point is regulated to the setpoint voltage VBG. In contrast, the average value of this reference voltage moves. It is noted therefore that the operation of this device is different from the operation of a device of the prior art in which it is the average value of the reference voltage that is regulated to the setpoint value, while the values of the reference voltage delivered to each end-of-convergence point move.

In addition, in the embodiment illustrated here, this regulation of the voltage value at each end-of-convergence point to the value of the setpoint voltage is independent of the activity. Depending on the technology used, the gate of the transistor M2, and consequently the gate of the transistor M4, may descend below ground, and therefore have a negative voltage.

To prevent this drawback, the PMOS transistors M2 and M4 mounted as followers, may be replaced by the structure illustrated in the right portion of FIG. 3, which makes it possible to emulate the PMOS transistors. More precisely, the two PMOS transistors M2 and M4 (the left portion of FIG. 3) are replaced by the structure of the right portion of FIG. 3 which comprises a first NMOS transistor M20 mounted as an NOT gate, coupled to a first capacitor C20, and a second NMOS transistor M40 also mounted as an NOT gate and coupled to a second capacitor C40.

A switched-capacitor module MCC is mounted in parallel with the first capacitor C20 and with the second capacitor C40. The gates of the transistors mounted as NOT gates M20 and M40 are connected together via the switched-capacitor module MMC. In operation, there is a transfer of charge between the capacitors C20 and C40 so long as the gate/source voltages of the transistors M20 and M40 are different. Such a structure makes it possible to reference everything relative to ground and in particular allows a better power supply rejection.

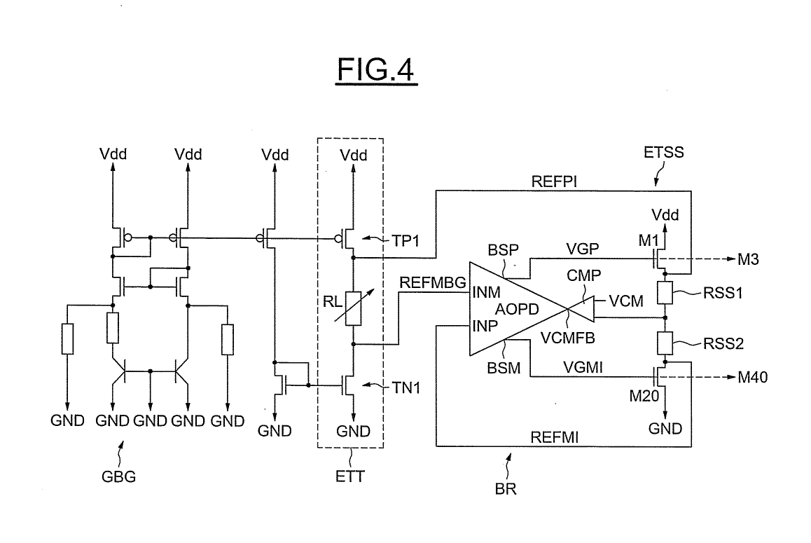

In the embodiment of FIG. 4, the two amplifiers AOPP and AOPM of FIG. 2 are replaced by a completely differential amplifier AOPD comprising two inputs INM and INP, and two outputs BSP and BSM. The output BSP is connected to the gate of the transistor M1 of the output stage ETTS while the output BSM is connected to the gate of the transistor M20 of the output stage ETTS. The output resistive module of FIG. 2 is formed in this instance of two identical resistors RSS1 and RSS2.

The regulation loop BR furthermore comprises a comparator CMP having a first input connected to the common terminal of the two resistors RSS1 and RSS2, and a second input in order to receive a common-mode voltage VCM. The output of the comparator delivers a voltage VCMFB to a common-mode input of the differential amplifier AOPD.

In this embodiment, the setpoint voltage is a band gap voltage generated by a band gap generator GBG of conventional structure. Note here that a band gap voltage is a voltage, of approximately 1.2 volts, independent of the temperature. More precisely, as illustrated in FIG. 4, the generator GBG comprises a voltage source capable of generating a band gap voltage coupled to current mirrors. This band gap voltage generator GBG furthermore comprises a terminal stage ETT having a variable resistor RL connected in series between two transistors TP1 and TN1 mounted as a current source.

The floating setpoint voltage REFMBG, present at one of the terminals of the resistor RL, is delivered to the input INM of the amplifier AOPD. The other input INP of the amplifier AOPD is connected to the terminal of the resistor RSS2 different from the terminal that is common with the resistor RSS1.

Similarly, the other terminal of the resistor RSS1, different from this common terminal, is connected to the other terminal of the variable resistor RL. Such an embodiment makes it possible, for a differential system, to generate the setpoint voltage (band gap voltage) in “floating” mode around the common-mode voltage VCM.

The three resistors of the band gap voltage generator GBG and the variable resistor RL are paired, so as to be able to generate the level required for the setpoint voltage. In addition, the fact that the resistor RL has an adjustable or programmable resistive value makes it possible, for example, to generate four different setpoint voltage levels, for example a level 2vpp; 1.6vpp; 1.4vpp or 1vpp, where vpp indicates the peak-peak voltage.

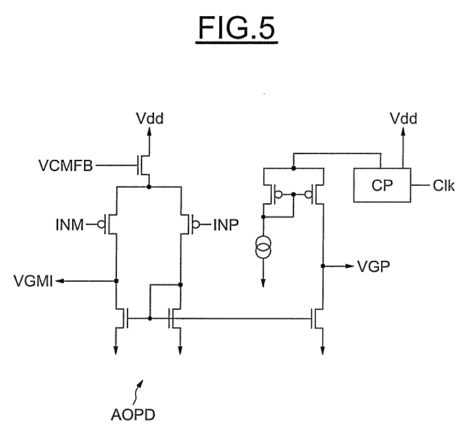

When the voltage VGP delivered by the operational amplifier AOPD has a value higher than the power supply voltage Vdd, provision is advantageously made, as illustrated in FIG. 5, to link a charge pump CP to the differential operational amplifier AOPD. The output of this charge pump is connected to the output BSP of the amplifier AOPD, and consequently to the gate of the NMOS transistor M1 of the output circuit of the output stage ETS.

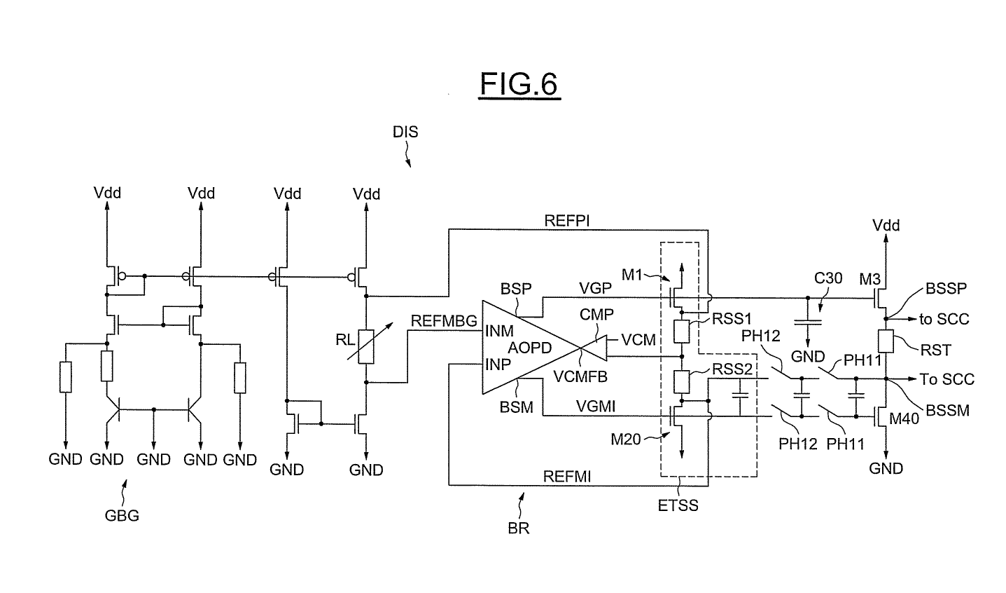

The embodiment of FIG. 6 repeats the various elements that have just been described with reference to the preceding figures and in particular the band gap voltage generator GBG, and the structure for emulating the PMOS transistors by the NMOS transistors mounted as diodes. In addition to these various elements, an additional capacitor C30 is connected between the gates of the transistors M1 and M3 and earth GND. This transistor in particular makes it possible to improve the power supply rejection.

Such an embodiment allows an improvement of the power supply rejection ratio (PSRR: well known to those skilled in the art). This parameter PSRR is improved relative to the power supply voltage Vdd. Specifically, in the event of variation of the power supply Vdd, there is an attenuation of the variation of the injected current due to the gain of the transistor M3.

The parameter PSRR is also improved relative to earth. Specifically, the capacitor C30 excites the gate of the transistor M1 simultaneously at the source of the transistor M20. The various embodiments that have just been described make it possible to provide many benefits. For example, in terms of noise, the regulation loop is a low-frequency loop with a decoupling capacitor having a considerable capacitive value (capacitor C30), and the result of this consequently is a high limitation of thermal noise. The additional stage, which is a replica of the output stage, is in fact a simple flow-through conduction stage. Accordingly, it makes no specific contribution and can therefore be considered a serial commutator.

The system is modular. Specifically, the number of additional circuits of the additional stage can be easily increased according in particular to the increase in the capacitive charge (C1, C2) or the switching frequency. It is not necessary, as in the prior art, to connect an external coupling capacitor to the output terminals of the reference voltage generation device. In particular this saves two pads in the input/output ring (IO ring) conventionally surrounding an integrated circuit. The system is particularly stable and it has a high PSRR parameter.

1-10. (canceled)

11. A device for generating a reference voltage, based on a setpoint voltage, for a switched-capacitor system, the device comprising:
a regulation loop comprising a first input, a second input, and an output stage, said first input to receive the setpoint voltage, and said output stage being arranged as a voltage follower and coupled to said second input; and
an additional stage arranged as a voltage follower, coupled to said output stage of said regulation loop, and configured to deliver the reference voltage.

12. A device according to claim 11, wherein said regulation loop and said additional stage have a differential structure; wherein the reference voltage comprises a differential reference voltage; and wherein said additional stage comprises first and second output terminals to deliver the differential reference voltage.

13. A device according to claim 12, wherein said output stage of said regulation loop has at least one output circuit comprising, coupled in series between two power supply terminals, a first output transistor mounted as a follower with an resistive output module and an output element forming a second output transistor mounted as a follower with said resistive output module.

14. A device according to claim 13, wherein said additional stage has at least one additional circuit, coupled in series between said power supply terminals, and comprising an additional NMOS transistor configured as a follower, with an additional resistive module and an additional element forming a third transistor mounted as a follower with said additional resistive module.

15. A device according to claim 14, wherein said first and third transistors have control terminals coupled together; and wherein said additional resistive module delivers the differential reference voltage.

16. A device according to claim 15, wherein said output element forming said second transistor is a PMOS transistor having a control terminal, and said additional element forming said third transistor is a PMOS transistor having a control terminal coupled to said control terminal of said second transistor.

17. A device according to claim 15, wherein said output element forming said second transistor and said additional element forming said third transistor comprise a first NMOS transistor configured as a NOT gate coupled to a first capacitor, a second NMOS transistor configured as a NOT gate coupled to a second capacitor, and a switched-capacitor module mounted in parallel with said first and second capacitors, said first and second NMOS transistors having control terminals coupled together via said switches-capacitor module.

18. A device according to claim 15, wherein said at least one output circuit is identical to said at least one additional circuit.

19. A device according to claim 12, further comprising a band gap voltage generator including a terminal stage having a resistor coupled in series between fourth and fifth transistors configured as a current source.

20. A device according to claim 19, wherein said regulation loop comprises a differential operational amplifier having a first input forming said first input thereof and coupled to said resistor of the said terminal stage to thereby receive a floating band gap voltage as a setpoint voltage, and a second input forming said second input of said regulation loop; wherein said resistive output module comprises two output resistors; and wherein said regulation loop further comprises a comparator having a first input coupled to a common terminal of said two output resistors, a second input to receive a common-mode voltage, and an output connected to a common-mode input of the differential amplifier, an other terminal of one of said two resistors being connected to said second input of the differential amplifier, the other of the two resistors being coupled to said resistor of said terminal stage.

21. A device according to claim 20, wherein said resistor of said terminal stage has an adjustable value.

22. A device according to claim 20, wherein said differential operational amplifier is associated with a charge pump having an output coupled to said control terminal of said first and third output transistors.

23. An apparatus comprising:
a switched-capacitor system;
a device for generating a reference voltage, based on a setpoint voltage, and coupled to said switched-capacitor system, the device comprising
a regulation loop comprising a first input, a second input, and an output stage, said first input to receive the setpoint voltage, and said output stage being arranged as a voltage follower and coupled to said second input, and
an additional stage arranged as a voltage follower, coupled to said output stage of said regulation loop, and configured to deliver the reference voltage.

24. An apparatus to claim 23, wherein said regulation loop and said additional stage have a differential structure; wherein the reference voltage comprises a differential reference voltage; and wherein said additional stage comprises first and second output terminals to deliver the differential reference voltage.

25. An apparatus according to claim 24, wherein said output stage of said regulation loop has at least one output circuit comprising, coupled in series between two power supply terminals, a first output transistor mounted as a follower with an resistive output module and an output element forming a second output transistor mounted as a follower with said resistive output module.

26. An apparatus according to claim 25, wherein said additional stage has at least one additional circuit, coupled in series between said power supply terminals, and comprising an additional NMOS transistor configured as a follower, with an additional resistive module and an additional element forming a third transistor mounted as a follower with said additional resistive module.

27. An apparatus according to claim 26, wherein said first and third transistors have control terminals coupled together; and wherein said additional resistive module delivers the differential reference voltage.

28. A method of making a device for generating a reference voltage, based on a setpoint voltage, for a switched-capacitor system, the method comprising:
forming a regulation loop having a first input, a second input, and an output stage;
configuring the first input to receive the setpoint voltage, and arranging the output stage as a voltage follower coupled to the second input;
arranging an additional stage as a voltage follower coupled to the output stage of the regulation loop and configured to deliver the reference voltage.

29. A method according to claim 28, wherein the regulation loop and the additional stage are formed and arranged, respectively, to have a differential structure; wherein the reference voltage comprises a differential reference voltage; and wherein the additional stage comprises first and second output terminals to deliver the differential reference voltage.

30. A method according to claim 29, wherein the output stage of the regulation loop is formed to have at least one output circuit comprising, coupled in series between two power supply terminals, a first output transistor mounted as a follower with an resistive output module and an output element forming a second output transistor mounted as a follower with the resistive output module.

31. A method according to claim 30, wherein the additional stage is arranged to have at least one additional circuit, coupled in series between the power supply terminals, and comprising an additional NMOS transistor configured as a follower, with an additional resistive module and an additional element forming a third transistor mounted as a follower with the additional resistive module.

32. A method according to claim 14, wherein the first and third transistors have control terminals coupled together; and wherein the additional resistive module delivers the differential reference voltage.

33. A method according to claim 15, wherein the output element forming the second transistor is a PMOS transistor having a control terminal, and the additional element forming the third transistor is a PMOS transistor having a control terminal coupled to the control terminal of the second transistor.
